(19) United States
(12) Patent Application Publication
(10) Pub. No.: US 2014/0264872 A1
(43) Pub. Date: Sep. 18, 2014

(54) Metal Capping Layer for Interconnect Applications

(71) Applicant: Taiwan Semiconductor Manufacturing Company, Ltd., Hsin-Chu (TW)

(72) Inventors: Yu-Hung Lin, Taichung City (TW); Bor-Jou Wei, Jiaoxi Township (TW); Chun-Chang Chen, Taichung City (TW); Yao Hsiang Liang, Hsin-Chu (TW); Yu-Min Chang, Hsin-Chu City (TW); Shih-Chi Lin, Hsin-Chu (TW)

(21) Appl. No.: 13/915,376

(22) Filed: Jun. 11, 2013

Related U.S. Application Data
(60) Provisional application No. 61/780,767, filed on Mar. 13, 2013.

(51) Int. Cl. H01L 23/532; H01L 21/768

(52) U.S. Cl. CPC H01L 23/53238; H01L 21/76841
USPC 257/751; 438/627

(57) ABSTRACT

An integrated circuit structure includes a semiconductor substrate and a dielectric layer over the semiconductor substrate. The integrated circuit structure further includes a conductive wiring in the dielectric layer. The integrated circuit structure also includes a first metallic capping layer over the conductive wiring and a second metallic capping layer over the first metallic capping layer. The second metallic capping layer has a width substantially the same as a width of the first metallic capping layer.

### RELATED CASES

This application claims priority to U.S. Provisional Patent Application No. 61/780,767, filed Mar. 13, 2013, and entitle “Metal Capping Layer for Interconnect Applications,” which application is incorporated herein by reference.

### BACKGROUND

Commonly used method for forming metal lines and vias is known as “damascene.” Generally, this method involves forming an opening in a dielectric layer, which separates the vertically spaced metallization layers. The opening is typically formed using conventional lithographic and etching techniques. After the formation, the opening is filled with copper or copper alloys to form a via or a trench. Excess metal material on the surface of the dielectric layer is then removed by chemical mechanical polish (CMP). The remaining copper or copper alloy forms vias and/or metal lines.

Copper has replaced aluminum because of its lower resistivity. However, copper still suffers from electro migration (EM) and stress migration (SM) reliability issues as geometries continue to shrink and current densities increase.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the relative dimensions of the various features may be arbitrarily increased or reduced for clarity of discussion.

FIG. 1 is a flowchart illustrating a method for fabricating a semiconductor device according to various aspects in one or more embodiments.

FIGS. 2-8 show schematic cross-sectional views of a semiconductor device at various stages of fabrication according to various aspects in one or more embodiments.

### DETAILED DESCRIPTION OF ILLUSTRATIVE EMBODIMENTS

It is understood that the following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

FIG. 1 is a flowchart illustrating a method 100 for fabricating a semiconductor device 200 according to various aspects in one or more embodiments. FIGS. 2-8 show schematic cross-sectional views of a semiconductor device 200 at various stages of fabrication according to one or more embodiments of the method 100 of FIG. 1. The semiconductor device 200 may be included in a microprocessor, memory cell, and/or other integrated circuit (IC). It is noted that the method of FIG. 1 does not produce a completed semiconductor device 200. A completed semiconductor device 200 may be fabricated using complementary metal-oxide-semiconductor (CMOS) technology processing. Accordingly, it is understood that additional processes may be provided before, during, and after the method 100 of FIG. 1, and that some other processes may only be briefly described herein. Also, FIGS. 1 through 8 are simplified for a better understanding of the present disclosure. For example, although the figures illustrate the semiconductor device 200, it is understood the IC may comprise a number of other devices comprising resistors, capacitors, inductors, fuses, etc.

Referring to FIGS. 1 and 2, the method 100 begins at step 102 wherein a first recess cavity 206 is formed in a first dielectric layer 204. In some embodiments, the first dielectric layer 204 is formed over a substrate 202. In some embodiments, the substrate 202 comprises a bulk substrate such as a crystalline silicon substrate (e.g., Si wafer). In alternative embodiments, the substrate 202 includes a top semiconductor layer of a compound wafer, such as a silicon-on-insulator substrate. In yet other embodiments, the substrate 202 is a bulk substrate or a top layer of a compound wafer comprising Ge, SiGe, a III-V material such as GaAs, InAs, a II-VI material such as ZeSe, ZnS, and the like, typically epitaxially grown. It is believed the III-V or II-VI materials may be particularly advantageous for forming illustrative devices because of the beneficial strain properties that can be derived from using III-V or II-VI properties, such as InAs, ZnS, and the like. Interconnect structures comprising metal line/via and methods of forming the same are provided. The intermediate stages of manufacturing preferred embodiments of the present invention are illustrated in FIGS. 2 through 9. Variations are then discussed.

The first dielectric layer 204 comprises any interlevel or intralevel dielectric including inorganic dielectrics or organic dielectrics. The first dielectric layer 204 may be porous or non-porous. Some examples of suitable dielectrics that can be used as the first dielectric layer 204 include, but are not limited to: SiO₂, silsesquioxanes, C doped oxides (i.e., organosilicates) that include atoms of Si, C, 0 and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The first dielectric layer 204 typically has a dielectric constant that is about 3.5 or less, which is referred to as a low-k dielectric layer. More preferably, the first dielectric layer 204 has a k value of less than about 2.5, and hence is sometimes referred to as an extra low-k (ELK) dielectric layer. These dielectrics generally have a lower parasitic crosstalk as compared with dielectric materials that have a higher dielectric constant than 4.0. The thickness of the first dielectric layer 204 may vary depending upon the dielectric material used as well as the exact number of dielectrics within the layer. The first dielectric layer 204 has a thickness, for example applied for an interconnect structure, ranging from about 150 nm to about 450 nm. In some embodiments, the first dielectric layer 204 is formed utilizing a deposition process including chemical vapor deposition (CVD), plasma enhanced chemical vapor deposition (PECV)), evaporation, chemical solution deposition, and spin-on coating.

The first recess cavity 206 is then formed within the first dielectric layer 204 by patterning the first dielectric layer 204. In some embodiments, the patterning process includes applying a lithography process (such as applying a photoresist, exposing the applied photoresist to a desired pattern of radiation and development) on the first dielectric layer 204, then applying an etching process (dry etching, wet etching or a combination thereof) to remove a portion of the first dielectric layer 204 to form the first recess cavity 206 within the first dielectric layer 204. In some embodiments, the first recess cavity 206 is a trench for forming a metal line. In some embodiments, the patterned photoresist is removed by a stripping process before forming the metal line.

Referring to FIGS. 1 and 3, the method 100 proceeds to step 104 in which a conductive layer 210 is formed in the first recess cavity 206. In some embodiments, the conductive layer 210 is formed to fill the first recess cavity 206 and over the first dielectric layer 204. In some embodiments, the conductive layer 210 includes copper or copper alloys. In some embodiments, the steps for forming the conductive layer 210 include depositing a thin seed layer of copper or copper alloy and then filling the first recess cavity 206 with a conductive material, such as copper or copper alloy. In some embodiments, the thin seed layer and the conductive material are formed by physical vapor deposition (PVD) and plating, respectively. In alternative embodiments, the conductive layer 210 includes other conductive materials, such as silver, gold, tungsten, aluminum, and the like.

In some embodiments, a barrier layer 208 is formed before forming the conductive layer 210. In some embodiments, the barrier layer 208 is formed on the exposed wall portions of the first dielectric layer 204 and within the first recess cavity 206. In some embodiments, the barrier layer 208 comprises one of Ti, Ta, TaN, TiN, Ru, RuN, RuTa, RuTaN, W, WN and any other material that can serve as a barrier to prevent conductive material from diffusing there through. The thickness of the barrier layer 208 may vary depending on the deposition process used in forming the same as well as the material employed. In some embodiments, the barrier layer 208 has a thickness ranging from about 0.5 nm to about 40 nm. In alternative embodiments, the barrier layer 208 has a thickness ranging from about 0.5 nm to about 20 nm. In some embodiments, the barrier layer 208 is formed by a deposition process including CVD, PECVD, PVD, atomic layer deposition (ALD), sputtering, chemical solution deposition, and plating.

Referring to FIGS. 1 and 4, the method 100 proceeds to step 106 in which a portion of the conductive layer 210 is removed. In some embodiments, the portion of the conductive layer 210 is removed by a chemical mechanical polish (CMP). In some embodiments, the CMP process removes the portion of the conductive layer 210 and the underlying barrier layer 208 above the first dielectric layer 204 to expose the upper surface of the first dielectric layer 204. In some embodiments, the CMP process removes the portion of the conductive layer 210 above the first recess cavity 206 while leaving another portion of the conductive layer 210 in the first dielectric layer 204. In some embodiments, the step of CMP leaves the conductive layer 210 in the first dielectric layer 204 having an upper surface substantially coplanar with the upper surface of the first dielectric layer 204. The remaining barrier layer 208 and the conductive layer 210 in the first dielectric layer 204 formed using single damascene processes may function as a first interconnect level.

A pretreatment may then be performed to treat the surface of conductive layer 210. In the present embodiment, the pretreatment includes a nitrogen-based gas treatment in a production tool, such as one used for plasma enhanced chemical vapor deposition (PECVD). The nitrogen-based gases, for example, include N₂, NH₃, and the like. In alternative embodiments, the pretreatment is performed in a hydrogen-based gas environment, which contains hydrogen-containing gases, such as H₂, NH₃, and the like. The pretreatment on the surface of conductive layer 210 has the function of reducing native metal oxide to metal (e.g., native copper oxide to copper) and removing chemical contamination from the surface of conductive layer 210.

Referring to FIGS. 1 and 5, the method 100 proceeds to step 108 in which a first capping layer 212 is formed over the remaining conductive layer 210. The first capping layer 212 may have a function of preventing voids formed at the interface of the successive levels of interconnects, therefore, to enhance electron migration (EM) reliability of the device 200. In some embodiments, the first capping layer 212 is formed on the upper exposed surface of the remaining conductive layer 210, i.e., atop the conductive layer 210 within the first dielectric layer 204. In some embodiments, the first capping layer 212 is formed of a bilayer structure including a second metallic capping layer 212b over a first metallic capping layer 212a. In some embodiments, the first capping layer 212 has a combined thickness within a range from about 1 nm to about 70 nm. Although the drawing shows the first capping layer 212 only covers the conductive layer 210, but not the barrier layer 208, one skilled in the art will realized that the first capping layer 212 may also extend onto top edges of the barrier layer 208.

The first metallic capping layer 212a may function as an adhesion layer providing sufficient adhesion to the underlying conductive layer 210. In some embodiments, the first metallic capping layer 212a comprises Co, Ir or Ru alone, or their alloy materials with at least one of W, B, P, Mo, or Re. That is, one of Co, Ir, and Ru with at least one of W, B, P, Mo, or Re. In the present embodiment, the first metallic capping layer 212a is a Co-containing metallic capping layer, such as CoWP. In some embodiments, the first metallic capping layer 212a has a thickness within a range from about 0.5 nm to about 20 nm. In alternative embodiments, the first metallic capping layer 212a has a thickness ranging from about 0.5 nm to about 10 nm. In some embodiments, the first metallic capping layer 212a is formed utilizing a selective deposition process including for example, a catalytic plating process or an electroless plating process. In alternative embodiments, a non-selective deposition process such as sputtering, ALD, and CVD can be used.

In some embodiments, the second metallic capping layer 212b is selectively formed on the surface of the first metallic capping layer 212a and has a width substantially similar to the width of the first metallic capping layer 212a. In some embodiments, the second metallic capping layer 212b is formed utilizing a selective deposition process including a catalytic plating process or an electroless plating process. In alternative embodiments, a non-selective deposition process such as sputtering, ALD, and CVD is used to from the second metallic capping layer 212b, hence, the second metallic capping layer 212b may have a width different from the width of the first metallic capping layer 212a.

In the present embodiment, the second metallic capping layer 212b is comprised of a different metal than that which is present in the first metallic capping layer 212a. In some embodiments, the second metallic capping layer 212b includes a material with a resistivity lower than the resistivity of the first metallic capping layer 212a to decrease the combined resistance of the first capping layer 212. In alternative embodiments, the second metallic capping layer 212b includes a material with a deposition rate higher than the deposition rate of the first metallic capping layer 212a to increase the throughput of the production. In some embodiments, the second metallic capping layer 212b is comprised of one of W, Ir, Ru, or alloys thereof. In some embodiments, the second metallic capping layer 212b has a thickness within a range from about 0.5 nm to about 50 nm. In alternative embodiments, the second metallic capping layer 212b has a thickness ranging from about 0.5 nm to about 10 nm.

Referring to FIGS. 1 and 6, the method 100 proceeds to step 110 in which a second dielectric layer 216 is formed over the first dielectric layer 204 and the second dielectric layer 216 includes second recess cavities 218 therein. The second dielectric layer 216 typically has a dielectric constant that is about 3.5 or less, which is referred to as a low-k dielectric layer. More preferably, the second dielectric layer 216 has a k value of less than about 2.5, and hence is sometimes referred to as an extra low-k (ELK) dielectric layer. In some embodiments, the second dielectric layer 216 comprises the dielectric material same as that of the first dielectric layer 204. The processing techniques and thickness ranges for the first dielectric layer 204 are also applicable here for the second dielectric layer 216. In alternative embodiments, the second dielectric layer 216 comprises a dielectric material different from the material of the first dielectric layer 204.

In some embodiments, an etch stop layer (ESL) 214 is formed between the first dielectric layer 204 and the second dielectric layer 216. The second recess cavities 218 are formed in the ESL 214 and the second dielectric layer 216 by a pattering and an etching processes as mentioned above. In some embodiments, the ESL 214 includes a material different from the first dielectric layer 204 or the second dielectric layer 216 to provide an etching selectivity during the process for forming the second recess cavities 218. In some embodiments, the ESL 214 includes silicon nitride, silicon carbide, silicon oxynitride, or combinations thereof.

In some embodiments, the second recess cavities 218 include an upper trench portion 218U for forming a conductive line subsequently. The second recess cavities 218 may further include a lower via portion 218L under the upper trench portion 218U for forming a conductive via subsequently. In the present embodiment, the lower via portion 218L exposes at least a portion of the upper surface of first capping layer 212. The conductive line and via formed using dual damascene processes may function as a second interconnect level over the first interconnect level.

Referring to FIGS. 1 and 7, the method 100 proceeds to step 112 in which a barrier layer 220 and conductors 222 are successively formed in the second recess cavities 218. In some embodiments, the barrier layer 220 is formed lining the walls of the second recess cavities 218 by a deposition process including CVD, PECVD, PVD, atomic layer deposition (ALD), sputtering, chemical solution deposition, and plating. In some embodiments, the barrier layer 220 comprises a material same as the material of the barrier layer 208. In some embodiments, the barrier layer 220 has a thickness within a range same as the barrier layer 208.

In some embodiments, the conductors 222 are continuously formed over the barrier layer 220 as the manner for forming the conductive layer 210. In some embodiments, the conductors 222 over-fill the recess cavities 218. In some embodiments, the conductors 222 include copper or copper alloys. In some embodiments, the steps for forming the conductors 222 further include depositing a thin seed layer of copper or copper alloy prior forming the copper or copper alloys. In some embodiments, a CMP process is provided to remove the excess barrier layer 220 and the conductors 222 on the surface of the second dielectric layer 216 while leaving the barrier layer 220 and the conductors 222 in the second dielectric layer 216 and/or in the ESL 214. The remaining barrier layer 220 and the conductors 222 in the second dielectric layer 216 may function as a second interconnect level. As illustrated in FIG. 7, the second interconnect level may electrically connect to the underlying first interconnect level through the first capping layer 212.

Referring to FIGS. 1 and 8, the method 100 proceeds to step 114 in which a second capping layer 224 is formed over the conductors 222. The second capping layer 224 may have a function of preventing voids formed at the interface of the successive levels of interconnects, therefore, to enhance electron migration (EM) reliability of the device 200. In some embodiments, the second capping layer 224 is formed as mentioned above for forming the first capping layer 212. In some embodiments, the second capping layer 224 is a bilayer including a second metallic capping layer 224b over a first metallic capping layer 224a. In some embodiments, the thickness of the first metallic capping layer 224a and the second metallic capping layer 224b are within the same range of the first metallic capping layer 212a and the second metallic capping layer 212b, respectively. Although the drawing shows the second capping layer 224 only covers the conductors 222, but not the barrier layer 220, one skilled in the art will realized that the second capping layer 224 may also extend onto top edges of the barrier layer 220.

The first metallic capping layer 224a may function as an adhesion layer providing sufficient adhesion to the underlying conductors 222. In some embodiments, the first metallic capping layer 224a comprises Co, Ir, or Ru alone, or their alloy materials with at least one of W, B, P, Mo, or Re. In some embodiments, the first metallic capping layer 224a comprises a material same as the material of the first metallic capping layer 212a. In the present embodiment, the second metallic capping layer 224b is comprised of a metal different from the metal present in the first metallic capping layer 212a. In some embodiments, the second metallic capping layer 224b includes a material with a resistivity lower than the resistivity of the first metallic capping layer 224a to decrease the combined resistance of the first capping layer 224. In alternative embodiments, the second metallic capping layer 224b includes a material with a deposition rate higher than the deposition rate of the first metallic capping layer 224a to increase the throughput of the production. In some embodiments, the second metallic capping layer 224b is comprised of one of W, Ir, Ru, or alloys thereof. In some embodiments, the first metallic capping layer 224a and the second metallic capping layer 224b are formed utilizing a selective deposition process including for example, a catalytic plating process or an electroless plating process. In alternative embodiments, a non-selective deposition process such as sputtering, ALD, and CVD can be used.

The embodiments of the present invention have several advantageous features. The first metallic capping layer may provide sufficient adhesion to the underlying conductor, therefore, it may result strong mechanical strength between the first metallic capping layer and the underlying conductor. In addition, the second metallic capping layer has a resistivity lower than the first metallic capping layer. Accordingly, the combined resistances of the first and the second metallic capping layers are reduced. Further, the second metallic capping layer may be formed with a deposition rate higher than the first metallic capping layer. Accordingly, the combined deposition time of the first and the second metallic capping layers is reduced, which causes the improvement in throughput.

In one embodiment, an integrated circuit structure includes a substrate, a dielectric layer over the substrate, a conductive wiring in the dielectric layer, a first metallic capping layer over the conductive wiring, and a second metallic capping layer over the first metallic capping layer. The second metallic capping layer has a width substantially the same as a width of the first metallic capping layer.

In another embodiment, an integrated circuit structure includes a semiconductor substrate, a low-k dielectric layer over the semiconductor substrate, an opening extending from a top surface of the low-k dielectric layer into the low-k dielectric layer, a barrier layer lining the opening, a copper-containing conductive line in the opening and on the barrier layer, a first metallic capping layer over the copper-containing conductive line, and a second metallic capping layer over the first metallic capping layer. The second metallic capping layer comprises a material different from a material of the first metallic capping layer.

In still another embodiment, a method includes forming a dielectric layer over a semiconductor substrate, forming a copper line in the dielectric layer, forming a first metallic capping layer over the copper line, and selectively forming a second metallic capping layer on the first metallic capping layer.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit structure comprising:
a substrate;
a dielectric layer over the substrate;
a conductive wiring in the dielectric layer;
a first metallic capping layer over the conductive wiring; and
a second metallic capping layer over the first metallic capping layer, wherein the second metallic capping layer has a width substantially the same as a width of the first metallic capping layer.

2. The integrated circuit structure of claim 1, wherein the second metallic capping layer comprises a material with a resistivity lower than a resistivity of a material of the first metallic capping layer.

3. The integrated circuit structure of claim 1, wherein the second metallic capping layer comprises a material different from a material of the first metallic capping layer.

4. The integrated circuit structure of claim 1, wherein the first metallic capping layer comprises Co, Ir, Ru, or alloys thereof.

5. The integrated circuit structure of claim 1, wherein the second metallic capping layer comprises W, Ir, Ru, or alloys thereof.

6. The integrated circuit structure of claim 5, wherein the first metallic capping layer and the second metallic capping layer have a combined thickness ranging from about 1 nm to about 70 nm.

7. The integrated circuit structure of claim 1 further comprising:
an etch stop layer over the second metallic capping layer;
a low-k dielectric layer over the etch stop layer; and
a via plug in the low-k dielectric layer, wherein the via plug penetrates an opening in the etch stop layer, and wherein the via plug is in contact with the second metallic capping layer.

8. The integrated circuit structure of claim 7, further comprising:
a metal line in the low-k dielectric layer contacting the via plug, and
a metal capping layer over the metal line.

9. The integrated circuit structure of claim 8, wherein the metal capping layer has a bi-layered structure.

10. An integrated circuit structure comprising:
a semiconductor substrate;
a low-k dielectric layer over the semiconductor substrate;
an opening extending from a top surface of the low-k dielectric layer into the low-k dielectric layer;
a barrier layer lining the opening;
a copper-containing conductive line in the opening and on the barrier layer;
a second metallic capping layer over the copper-containing conductive line; and
a first metallic capping layer positioned between the first metallic capping layer and the copper-containing conductive line, wherein the first metallic capping layer comprises a material different from a material of the second metallic capping layer.

11. The integrated circuit structure of claim 10, wherein the first metallic capping layer comprises Co, Ir, Ru, or alloys thereof.

12. The integrated circuit structure of claim 10, wherein the second metallic capping layer comprises W, Ir, Ru, or alloys thereof.

13. The integrated circuit structure of claim 10, wherein the material of the second metallic capping layer has a resistivity lower than a resistivity of a the material of the first metallic capping layer.

14. The integrated circuit structure of claim 10, wherein the first metallic capping layer and the second metallic capping layer have a combined thickness ranging from about 1 nm to about 70 nm.

15. The integrated circuit structure of claim 10, wherein the second metallic capping layer has a width substantially the same as a width of the first metallic capping layer.

16. A method, comprising:
forming a dielectric layer over a semiconductor substrate;
forming a copper line in the dielectric layer;
forming a first metallic capping layer over the copper line; and
forming a second metallic capping layer over the first metallic capping layer, wherein the second metallic capping layer has a width substantially the same as a width of the first metallic capping layer.

17. The method of claim 16, wherein a deposition rate for forming the second metallic capping layer is higher than a deposition rate for forming the first metallic capping layer.

18. The method of claim 16, wherein the first metallic capping layer and the second metallic capping layer comprise different materials.

19. The method of claim 16, wherein the first metallic capping layer is selectively formed on the copper line.

20. The method of claim 16, wherein the second metallic capping layer has a resistivity lower than a resistivity of the first metallic capping layer.
